(19) United States
(12) Patent Application Publication
(10) Pub. No.: US 2016/0169989 A1
(43) Pub. Date: Jun. 16, 2016

(54) MAGNETIC FIELD MEASURING APPARATUS

(71) Applicant: HITACHI, LTD., Tokyo (JP)

(72) Inventors: Seiichi SUZUKI, Tokyo (JP); Taro OSABE, Tokyo (JP); Yudai KAMADA, Tokyo (JP); Ryuzo KAWABATA, Tokyo (JP); Akihiko KANDORI, Tokyo (JP)

(73) Assignee: Hitachi, Ltd., Tokyo (JP)

(21) Appl. No.: 14/904,460

(22) PCT Filed: Aug. 8, 2013
(86) PCT No.: PCT/JP2013/071533

§ 371 Date: Jan. 12, 2016

(51) Int. Cl. G01R 33/26

(52) U.S. Cl. CPC G01R 33/26

(57) ABSTRACT

An object of the present invention is to provide a technique to improve a manufacturing yield of a gas cell included in a magnetic field measuring apparatus. A gas cell GC according to an embodiment is characterized in that, for example, a cavity CAV includes an opening OP1 and an opening OP2, a plane size of the opening OP1 becomes larger than a plane size of the opening OP2 in the openings OP1 and OP2 included in the cavity CAV. Especially, according to the embodiment, the opening OP2 is included in the opening OP1 in plan view. Consequently, a width of the opening OP1 coming into contact with an upper surface of the sealing substrate 1S becomes larger than a width of the opening OP2 coming into contact with a lower surface of the sealing substrate 2S.

### TECHNICAL FIELD

The present invention relates to a magnetic field measuring apparatus.

### BACKGROUND ART

For example, PTL 1 (JP 2013-007720 A) and PTL 2 (JP 2012-183290 A) disclose an optical pumping magnetometer, as a magnetic field measuring apparatus, including a gas cell filled with an alkali metal gas inside by using such as a silicon substrate. Herein, for example, the above-described gas cell is made of glass in a conventional technique. However, a substrate is machined by using micro electro mechanical systems (MEMS) in a technique described in PTL 1, and a gas cell is formed in which a glass substrate, a substrate, and a glass substrate are laminated in this order. Further, a gas cell is formed by assembling multiple plate materials in a technique described in PTL 2.

### CITATION LIST

### Patent Literatures

PTL 1: JP 2013-007720 A

PTL 2: JP 2012-183290 A

### SUMMARY OF INVENTION

### Technical Problem

For example, in a process for manufacturing a gas cell using an MEMS technique, a through hole is formed on a silicon substrate (Si substrate). After a first glass substrate is bonded on a lower surface of the Si substrate, for example, a second glass substrate is bonded on an upper surface of the Si substrate by introducing an alkali metal.

An example of a technique for introducing an alkali metal includes a technique in which a compound including the alkali metal is used since the alkali metal is unstable in the atmosphere. Specifically, in this technique, a micropipette and an inkjet coating apparatus are used by using a compound, as a solution, including an alkali metal, and the solution is dropped on a first glass substrate exposed at a bottom of a through hole. After the solution is dropped, the solution is dried, and then the through hole is sealed by a second glass substrate. Subsequently, by using such as photolysis and pyrolysis with respect to a compound existing in a dry state in a through hole, an alkali metal gas is produced from the compound and filled in the sealed through hole.

However, when an inventor of the present invention has considered the above-described technique for introducing an alkali metal, the inventor has found that there has been room for improvement to be described below. Specifically, the inventor has found that, in the above-described technique for introducing an alkali metal, for example, a dropped solution has creeped up on a side surface of a through hole due to surface tension, and also a phenomenon has occurred in which the solution spills over an outside of the through hole from a side surface thereof. In the case where this phenomenon occurs, the compound is precipitated from a side surface of the through hole to an outside if the solution is dried. Then, the through hole is sealed by the second glass substrate. However, as a result of that the compound is precipitated from a side surface of the through hole to an outside, the compound is inserted between the Si substrate and the second glass substrate in a sealing process.

Therefore, since the compound is inserted between the Si substrate and the second glass substrate, a bonding defect between the Si substrate and the second glass substrate occurs, and the bonding defect portion becomes a leak path. Accordingly, it becomes difficult to fully seal a gas in a gas cell, and a yield of the gas cell might be reduced. Specifically, in the above-described technique for introducing an alkali metal, there is a room for further improvement from a viewpoint of improving a manufacturing yield of a gas cell.

Herein, a case where an alkali metal gas is used is described as a specific representative example. However, the above-described improvement is widely possible in the case where, regardless of a gas type, a gas to be filled in a gas cell is introduced in a state in which the gas is a solution compound.

An object of the present invention is to provide a technique for improving a manufacturing yield of a gas cell included in a magnetic field measuring apparatus.

Other issues and new characteristics will be specified from descriptions described herein and attached drawings.

### Solution to Problem

A magnetic field measuring apparatus according to an embodiment described herein includes a gas cell including a first cavity for filling a gas. The gas cell includes (a) a first sealing substrate, (b) a second sealing substrate, (c) a substrate member sandwiched between the first sealing substrate and the second sealing substrate, and (d) the first cavity penetrating the substrate member. The first cavity includes (e1) a first opening coming into contact with an upper surface of the first sealing substrate and (e2) a second opening coming into contact with a lower surface of the second sealing substrate. At this time, the first opening and the second opening are communicated each other, and accordingly the first cavity is formed. A plane size of the first opening is larger than a plane size of the second opening.

### Advantageous Effects of Invention

According to an embodiment described herein, a manufacturing yield of a gas cell included in a magnetic field measuring apparatus can be improved. In other words, according to the embodiment, reliability of the gas cell included in the magnetic field measuring apparatus can be improved.

### BRIEF DESCRIPTION OF DRAWINGS

FIG. 1 is a view illustrating a schematic configuration example of a magnetic field measuring apparatus according to a first embodiment.

FIG. 2 is a plan view illustrating a schematic appearance configuration of a gas cell included in the magnetic field measuring apparatus according to the first embodiment.

FIG. 3 is an enlarged plan view illustrating a sealing region of the gas cell according to the first embodiment.

FIG. 4 is a sectional view cut on line A-A illustrated in FIG. 3.

FIG. 5 is a sectional view illustrating a manufacturing process of the gas cell according to the first embodiment.

FIG. 6 is a sectional view illustrating a manufacturing process of the gas cell subsequent to the process illustrated in FIG. 5.

FIG. 7 is a sectional view illustrating a manufacturing process of the gas cell subsequent to the process illustrated in FIG. 6.

FIG. 8 is a sectional view illustrating a manufacturing process of the gas cell subsequent to the process illustrated in FIG. 7.

FIG. 9 is a sectional view illustrating a manufacturing process of the gas cell subsequent to the process illustrated in FIG. 8.

FIG. 10 is a sectional view illustrating a manufacturing process of the gas cell subsequent to the process illustrated in FIG. 9.

FIG. 11 is an enlarged plan view illustrating a sealing region of a gas cell according to a second embodiment.

FIG. 12 is a sectional view cut on line A-A illustrated in FIG. 11.

FIG. 13 is a sectional view illustrating a manufacturing process of the gas cell according to the second embodiment.

FIG. 14 is a sectional view illustrating a manufacturing process of the gas cell subsequent to the process illustrated in FIG. 13.

FIG. 15 is a sectional view illustrating a manufacturing process of the gas cell subsequent to the process illustrated in FIG. 14.

FIG. 16 is a sectional view illustrating a manufacturing process of the gas cell subsequent to the process illustrated in FIG. 15.

FIG. 17 is a sectional view illustrating a manufacturing process of the gas cell subsequent to the process illustrated in FIG. 16.

FIG. 18 is a sectional view illustrating a manufacturing process of the gas cell subsequent to the process illustrated in FIG. 17.

FIG. 19 is a sectional view illustrating a manufacturing process of the gas cell subsequent to the process illustrated in FIG. 18.

FIG. 20 is an enlarged plan view illustrating a sealing region of a gas cell according to a third embodiment.

FIG. 21 is a sectional view cut on line A-A illustrated in FIG. 20.

FIG. 22 is a sectional view illustrating a manufacturing process of the gas cell according to the third embodiment.

FIG. 23 is a sectional view illustrating a manufacturing process of the gas cell subsequent to the process illustrated in FIG. 22.

FIG. 24 is a sectional view illustrating a manufacturing process of the gas cell subsequent to the process illustrated in FIG. 23.

FIG. 25 is a sectional view illustrating a manufacturing process of the gas cell subsequent to the process illustrated in FIG. 24.

FIG. 26 is a sectional view illustrating a manufacturing process of the gas cell subsequent to the process illustrated in FIG. 25.

FIG. 27 is a sectional view illustrating a manufacturing process of the gas cell subsequent to the process illustrated in FIG. 26.

FIG. 28 is a sectional view illustrating a gas cell according to a variation of the third embodiment.

FIG. 29 is an enlarged plan view illustrating a sealing region of a gas cell according to a fourth embodiment.

FIG. 30 is a sectional view cut on line A-A illustrated in FIG. 29.

FIG. 31 is a sectional view illustrating a manufacturing process of the gas cell according to the fourth embodiment.

FIG. 32 is a sectional view illustrating a manufacturing process of the gas cell subsequent to the process illustrated in FIG. 31.

FIG. 33 is a sectional view illustrating a manufacturing process of the gas cell subsequent to the process illustrated in FIG. 32.

FIG. 34 is a sectional view illustrating a manufacturing process of the gas cell subsequent to the process illustrated in FIG. 33.

FIG. 35 is a sectional view illustrating a manufacturing process of the gas cell subsequent to the process illustrated in FIG. 34.

### DESCRIPTION OF EMBODIMENTS

If necessary for convenience in embodiments to be described below, the embodiments will be described by dividing into multiple sections or embodiments. However, unless especially specified, those are related to each other, and one embodiment is such as a variation, a detail, and a supplemental description in part or whole of another embodiment.

Further, in the embodiments described below, in the case where a number of elements (including a quantity, a value, an amount, and a range) are specified, it is not limited to a specific number, and it may be equal to, or greater, or less than the specific number, except for the case of being especially specified and being obviously limited to a specific number in principle.

Furthermore, in the embodiments described below, components thereof (including such as an element step) is not necessarily essential, except for the case of being especially specified and the case where it is considered to be obviously essential in principle.

Similarly, in the embodiments described below, when a shape and a positional relation of such as components are described, a substantially approximate or similar shape and relation are included, except for the case of being especially specified and the case where it is considered not to be approximate or similar in principle. This can be applicable to the above-described value and range.

Further, in every drawing for describing the embodiments, same members are denoted by the same reference signs in principle, and redundant descriptions thereof are omitted. Even a plan view may be hatched for clarification.

### First Embodiment

### Configuration of Magnetic Field Measuring Apparatus

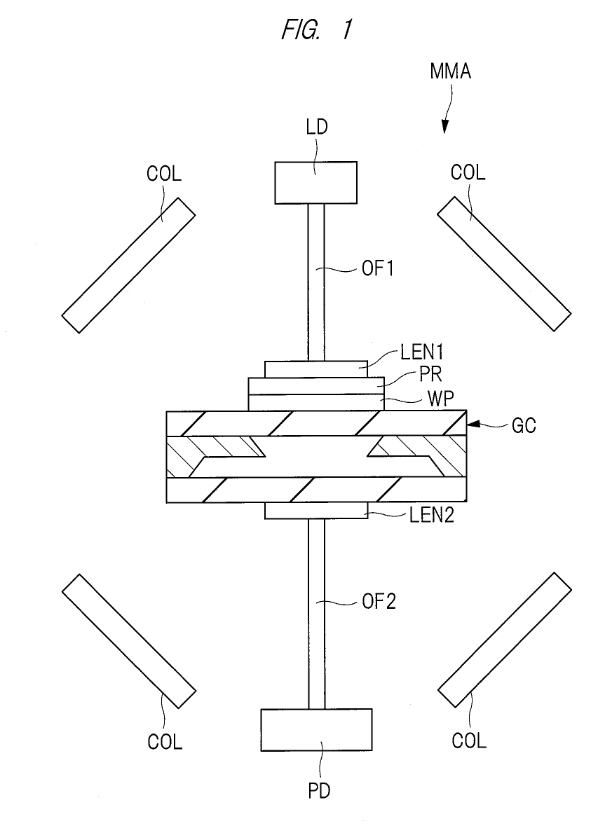

FIG. 1 is a view illustrating a schematic configuration example of a magnetic field measuring apparatus MMA according to a first embodiment. In FIG. 1, components of the magnetic field measuring apparatus MMA according to the first embodiment can be roughly classified into an optical system, a magnetic system, and a gas cell GC.

First, the optical system includes a semiconductor laser LD, an optical fiber OF1, a collimator lens LEN1, a polarizer PR, a wavelength plate WP, a condenser lens LEN2, an optical fiber OF2, and a photo detector PD.

The semiconductor laser LD functions as a light source which irradiates the gas cell GC with a light (pumping light) and emits a monochromatic laser light. For example, the semiconductor laser LD has a configuration in which an active layer is sandwiched by clad layers. In the semiconductor laser LD, inverted distribution is formed by injecting an electron and a hole into an active layer, and a laser light is emitted in which a phase is adjusted by using induced emission from a conduction band to a valence band.

The optical fiber OF1 functions as an optical path of a laser light emitted from the semiconductor laser LD. In this optical fiber OF1, for example, a core layer having a high reflective index is formed at a center portion, and a clad layer having a low reflective index is formed so as to surround the core layer. In the optical fiber OF1, a laser light is totally reflected on a boundary surface between the core layer and the clad layer. Therefore, the laser light efficiently passes through the core layer.

Next, the collimator lens LEN1 has a function to convert, into a parallel light, a laser light emitted from the semiconductor laser LD and passed through the optical fiber OF1. Subsequently, the polarizer PR and the wavelength plate WP convert, into a circular polarizing laser light, a parallel light emitted from the collimator lens LEN1. The circular polarizing laser light converted by the polarizer PR and the wavelength plate WP is emitted in the gas cell GC.

The condenser lens LEN2 condenses a laser light which has passed through the gas cell GC. The optical fiber OF2 forms a light path through which the laser light condensed by the condenser lens LEN2 passes. Further, the photo detector PD has a function to detect the laser light which has passed through the optical fiber OF2, and for example, and the photo detector PD includes a photodiode.

A magnetic system, for example, includes a coil COL which functions as a magnetic field production unit for producing a magnetic field. The coil COL can produce a static magnetic field and an alternating magnetic field. In FIG. 1, as a magnetic system, two pairs of the coils COL are disposed at a position perpendicular to each other as an example. However, if the magnetic system can apply a static magnetic field and an alternating magnetic field to the gas cell GC, the coil COL may not be disposed as illustrated in FIG. 1.

Next, the gas cell GC is filled with an alkali metal gas such as cesium, potassium, rubidium, and the gas cell GC is disposed so that a laser light is emitted from the semiconductor laser LD to the filled alkali metal gas through an optical system. A laser light entered into the gas cell GC is partially emitted from the gas cell GC, and the emitted laser light is entered into the photo detector PD by the optical system. Further, the gas cell GC is disposed so that a static magnetic field and an alternating magnetic field produced in the coil COL are applied.

In the case of disposing the semiconductor laser LD and the photo detector PD on an outer side of the coil COL through the optical fiber OF1 and the optical fiber OF2, a current and an electric wiring for driving the semiconductor laser LD and a current and an electric wiring from the photo detector PD prevent that a measurement error caused when uniformity of a magnetic field applied from the coil COL is deteriorated.

However, in the case where the above-described current and electric wiring are less effective, the semiconductor laser LD may be directly disposed on the collimator lens LEN1 without using the optical fiber OF1. Further, the photo detector PD may be directly disposed on the condenser lens LEN2 without using the optical fiber OF2, and the photo detector PD can be disposed so as to directly come into contact with the gas cell GC without using the condenser lens LEN2. In this case, the magnetic field measuring apparatus MMA according to the first embodiment can be downsized.

Furthermore, a light entered into the gas cell GC may be a circular polarizing light. Therefore, if the magnetic field measuring apparatus MMA can emit a circular polarizing light, any of components included in the optical system, such as the semiconductor laser LD, the collimator lens LEN1, the polarizer PR, the wavelength plate WP, the optical fiber OF1, and the optical fiber OF2, can be omitted, arrangement of the components can be switched, and a new component can be added.

Further, the magnetic field measuring apparatus MMA according to the first embodiment can use multiple gas cells GC arranged in an array. In this case, the semiconductor laser LD and the coil COL can be commonly used in the multiple gas cells GC. For example, laser lights emitted from the semiconductor laser LD can be distributed to each of the multiple gas cells GC, and a common magnetic field from the coil COL can be applied to the multiple gas cells GC.

Operation of Magnetic Field Measuring Apparatus

The magnetic field measuring apparatus MMA according to the first embodiment has a configuration as described above. An operation for measuring an external magnetic field (ΔB) existing in an external environment will be described below.

In FIG. 1, a laser light emitted from the semiconductor laser LD is converted into a parallel light by the collimator lens LEN1 after passing through the optical fiber OF1 and then converted into a circular polarizing laser light by passing through the polarizer PR and the wavelength plate WP. Then, the circular polarizing laser light is entered into the gas cell GC. Further, a static magnetic field (B) is applied from the coil COL to the gas cell GC. Due to a Zeeman effect caused by the static magnetic field (B), Zeeman splitting occurs in an energy level of an alkali metal atom included in a gas in the gas cell GC.

In this state, when a circular polarizing laser light enters into the gas cell GC, the circular polarizing laser light interacts with an alkali metal atom in the gas cell GC. Specifically, by a circular polarizing laser light, an electron of the alkali metal atom is excited between specific levels splitted by the Zeeman effect, and the excited electron is fallen to multiple ground levels splitted by the Zeeman effect at an equal probability. By repeating exciting and falling of the electron, in the multiple ground levels splitted by the Zeeman effect, electrons existing in the ground levels contributing to the excitation are reduced, and electrons existing in the ground levels not contributing to the excitation are increased. Consequently, electrons exist locally in the ground levels not contributing to the excitation (optical pumping). This means that electrons exist locally in a level having a specific spin state, and an alkali metal atom is spin-polarized. Thus, by using an optical pumping technique, alkali metal atoms in the gas cell GC can be spun in a specific direction.

Then, a synthesized magnetic field (B+ΔB) in which a static magnetic field and an external magnetic field are combined is applied to the gas cell GC. Polarized alkali metal atoms spin around the synthesized magnetic field by precession (Lamore precession). At this time, precession frequency in the precession is proportional to intensity of the applied synthesized magnetic field.

The magnetic field measuring apparatus MMA according to the first embodiment further applies an alternating magnetic field in addition to the static magnetic field (B) from the coil COL. When the frequency of an alternating magnetic field is gradually changed, and a frequency of the alternating magnetic field coincides with a precession frequency of the above-described precession, optical magnetic double resonance occurs, and an output light from the gas cell GC is modulated by the precession frequency (resonance frequency). The output light modulated by the precession frequency is detected by the photo detector PD via the condenser lens LEN2 and the optical fiber OF2. At this time, a modulation frequency of the output light is equal to the precession frequency. Therefore, the precession frequency can be known by detecting the modulation frequency of the output light by the photo detector PD. The precession frequency is proportional to a synthesized magnetic field (B+ΔB) via a proportional constant specific to an alkali metal atom. Therefore, in consideration that the proportional constant is already known, the applied static magnetic field (B) is also already known, and a precession frequency is known from a modulation frequency of an output light, it is found that an external magnetic field (ΔB) can be measured.

As described above, according to the magnetic field measuring apparatus MMA according to the first embodiment, when a precession frequency of a precession associated with spin polarization of an alkali metal atom sealed in the gas cell GC is indirectly measured by optical magnetic double resonance, it is found that an external magnetic field (ΔB) can be measured. Especially, in the magnetic field measuring apparatus MMA according to the first embodiment, the gas cell GC in which alkali metal gas (alkali metal atoms) are filled plays an important role as a sensor. Accordingly, it is found that enhancement of reliability of the gas cell GC is needed to improve measurement accuracy of the external magnetic field (ΔB). Especially, sealing of an alkali metal gas in the gas cell GC is important. If sealing in the gas cell GC is insufficient, an alkali metal gas is discharged from the leak path. In this case, a laser light entered into the gas cell GC and an alkali metal gas interacting with the laser light are reduced, and it has an adverse effect on measurement of the external magnetic field (ΔB).

The gas cell GC included in the magnetic field measuring apparatus MMA is focused in the first embodiment so as to reduce a sealing failure of an alkali metal gas in the gas cell GC. A technical idea for reducing the sealing failure according to the first embodiment will be described below.

Configuration of Gas Cell According to First Embodiment

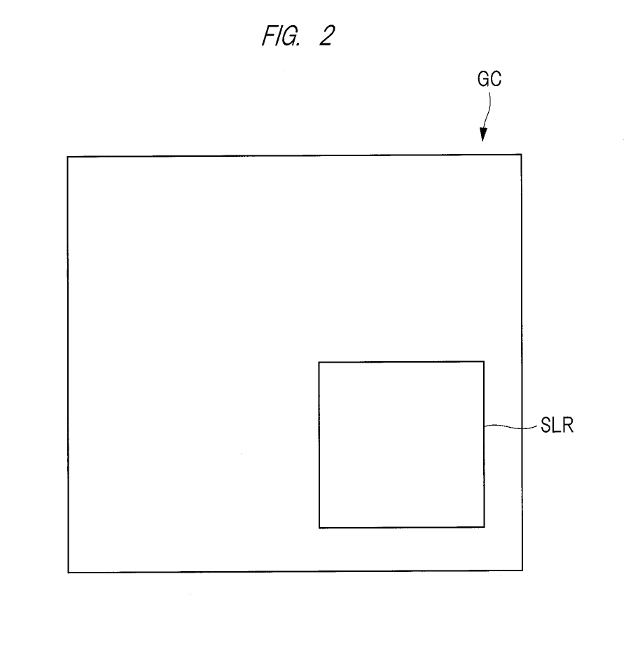

FIG. 2 is a plan view illustrating a schematic appearance configuration of the gas cell GC included in the magnetic field measuring apparatus according to the first embodiment. As illustrated in FIG. 2, for example, the gas cell GC according to the first embodiment has a rectangular shape and includes a sealing region SLR. The sealing region SLR also has a rectangular shape, and for example, an alkali metal gas is filled in the sealing region SLR. A plane size of the gas cell GC is larger than a plane size of the sealing region SLR so that the sealing region SLR can be conveyed without being damaged and, for example, a region other than the sealing region SLR can be held by such as a tweezers.

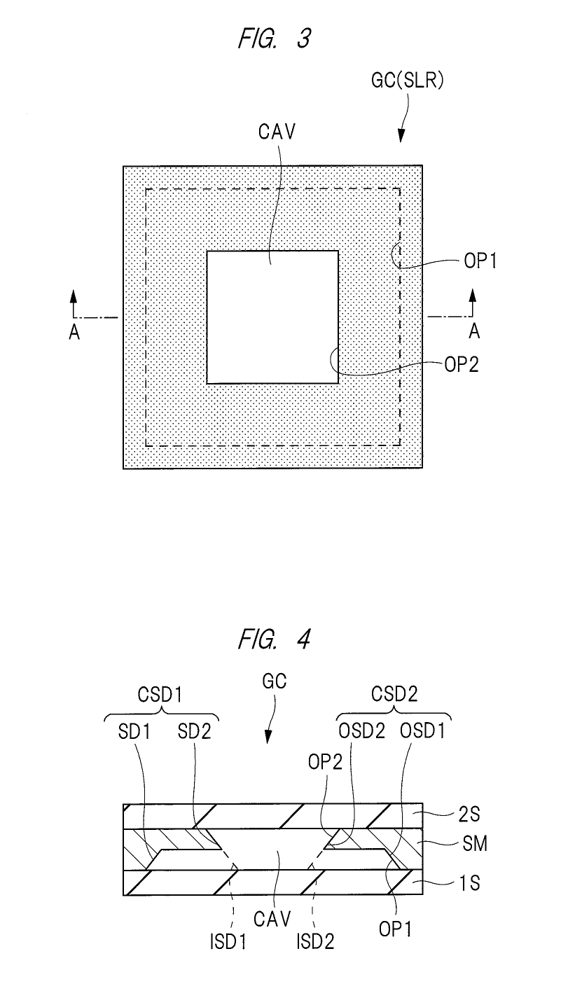

Next, FIG. 3 is an enlarged plan view illustrating the sealing region SLR of the gas cell GC illustrated in FIG. 2. In FIG. 3, for example, rectangular openings OP1 and OP2 are provided in the sealing region SLR of the gas cell GC. A cavity CAV is formed by the openings OP1 and OP2. As illustrated in FIG. 3, a plane size of the opening OP1 is larger than a plane size of the opening OP2 In plan view, the opening OP2 is included in the opening OP1. Shapes of the openings OP1 and OP2 are not limited to a rectangular shape and may be a polygonal shape or a circular shape. Therefore, a plane shape of the cavity CAV including the openings OP1 and OP2 is not limited to a rectangular shape and may be a polygonal shape or a circular shape.

Next, FIG. 4 is a sectional view cut on line A-A illustrated in FIG. 3. As illustrated in FIG. 4, the gas cell GC according to the first embodiment includes sealing substrates 1S and 2S, and a substrate member SM is disposed so as to be sandwiched between the sealing substrates 1S and 2S. In other words, the substrate member SM is mounted on the sealing substrate 1S, and the sealing substrate 2S is disposed on the substrate member SM. The sealing substrates 1S and 2S include, for example, a member translucent to a laser light (irradiation light) emitted from the semiconductor laser LD illustrated in FIG. 1 to the gas cell GC. Specifically, for example, the sealing substrates 1S and 2S are formed of a borosilicate glass. On the other hand, for example, a silicon substrate (Si substrate) frequently used in a semiconductor manufacturing technique and having machining results is used for the substrate member SM sandwiched between the sealing substrates 1S and 2S.

As described above, in the sealing region SLR of the gas cell GC according to the first embodiment, the sealing substrate 1S is disposed on a lower surface of the substrate member SM, and also the sealing substrate 2S is disposed on an upper surface of the substrate member SM. Specifically, the sealing region SLR has a three layer structure including a glass, a substrate member, and a glass. At this time, for example, the sealing substrate 1S functions as a support member which supports the substrate member SM. On the other hand, the sealing substrate 2S functions as a lid member which covers the substrate member SM.

Next, as illustrated in FIG. 4, in the gas cell GC according to the first embodiment, the cavity CAV is formed on the substrate member SM sandwiched between the sealing substrates 1S and 2S, and the cavity CAV penetrates the substrate member SM in a thickness direction. As illustrated in FIG. 4, the cavity CAV includes the opening OP1 coming into contact with an upper surface of the sealing substrate 1S and the opening OP2 coming into contact with a lower surface of the sealing substrate 2S. The cavity CAV is formed when the openings OP1 and OP2 communicate in a thickness direction. The cavity CAV is hermetically sealed by the upper surface of the sealing substrate 1S and the lower surface of the sealing substrate 2S.

At least, an alkali metal gas, such as cesium, potassium, and rubidium are filled in the cavity CAV. However, in addition to the above-described alkali metal gas, a nitrogen gas, a rare gas, or a mixture gas thereof may be included in the cavity CAV.

In this case, an advantage to be described below is obtained. Specifically, when the magnetic field measuring apparatus according to the first embodiment measures an external magnetic field, an alkali metal gas (alkali metal atom) filled in the cavity CAV is spin-polarized so as to spin in the same direction by irradiation of a pumping light. However, when an alkali metal gas collides with an inner wall of the cavity CAV, spin polarization is disturbed. Therefore, it is preferable that an alkali metal gas does not collide with the inner wall of the cavity CAV. On this point, even if a nitrogen gas and a rare gas collide with an alkali metal gas, spin polarization of an alkali metal gas is not easily disturbed. Therefore, spin polarization of an alkali metal gas can be easily maintained by filling a nitrogen gas and a rare gas in the cavity CAV with an alkali metal gas. Specifically, there are two advantages of introducing a nitrogen gas and a rare gas. One advantage is that spin polarization of an alkali metal gas is not easily disturbed even if an nitrogen gas and a rare gas collide with the alkali metal gas. Another advantage is that spin polarization of an alkali metal gas can be easily maintained since a probability in which an alkali metal gas collides with an inner wall of the cavity CAV is reduced by introducing a nitrogen and a rare gas.

Further, it is effective that, for example, an inner wall of the cavity CAV is coated by paraffin. This is because, in the case where the inner wall of the cavity CAV is coated by paraffin, spin polarization is not easily disturbed even if an alkali metal gas collides with an inner wall of the cavity CAV. Therefore, from a viewpoint of maintaining spin polarization of an alkali metal gas filled in the cavity CAV, in other words, maintaining spin information of the alkali metal gas, it is preferable to apply a configuration in which a nitrogen gas and a rare gas are introduced in the cavity CAV with an alkali metal gas and a configuration in which an inner wall of the cavity CAV is coated by paraffin.

Further, a gas production material (compound) in a solid state and a liquid state which produces an alkali metal gas and a solid and a liquid of an excessive alkali metal might exist in the cavity CAV. However, since the gas production material in a solid state and a liquid state and a solid and a liquid of the excessive alkali metal are not necessarily exist, these materials are not illustrated in FIGS. 3 and 4.

Since it is concerned that the above-described gas production material and excessive alkali metal (solid and liquid) remaining in the cavity CAV become a shielding material which reduces light intensity of a laser light passing through the cavity CAV, from a viewpoint of preventing reduction in the light intensity of a laser light passing through the cavity CAV, preferably a small amount of the above-described gas production material and excessive alkali metal (solid and liquid) is remained, and further preferably the above-described gas production material and excessive alkali metal are not remained.

In the gas cell GC according to the first embodiment, a configuration is assumed in which a laser light is emitted to the cavity CAV from the sealing substrate 2S side to the sealing substrate 1S side illustrated in FIG. 4. However, the configuration is not limited thereto, and, for example, a laser light may be emitted to the cavity CAV from the sealing substrate 1S side to the sealing substrate 2S side illustrated in FIG. 4.

Characteristics of Gas Cell According to First Embodiment

Next, a characteristic point of the gas cell GC according to the first embodiment will be described. The gas cell GC according to the first embodiment is characterized in that, for example, as illustrated in FIG. 3, the cavity CAV includes the openings OP1 and OP2, and a plane size of the opening OP1 is larger than a plane size of the opening OP2 in the openings OP1 and OP2 included in the cavity CAV. Especially, according to the first embodiment, as illustrated in FIG. 3, the opening OP2 is included in the opening OP1 in plan view. Consequently, as illustrated in FIG. 4, a width of the opening OP1 coming into contact with an upper surface of the sealing substrate 1S becomes larger than a width of the opening OP2 coming into contact with a lower surface of the sealing substrate 2S.

The above-described characteristics of the gas cell GC can be expressed as described below. For example, in FIG. 4, a side surface CSD1 of the cavity CAV includes a side surface SD1 of the opening OP1 and a side surface SD2 of the opening OP2. Similarily, a side surface CSD2 facing the side surface CSD1 of the cavity CAV includes a side surface OSD1 facing the side surface SD1 of the opening OP1 and a side surface OSD2 facing the side surface SD2 of the opening OP2.

In such a configuration, the characteristic configuration according to the first embodiment in which a plane size of the opening OP1 is larger than a plane size of the opening OP2, and the opening OP2 is included in the opening OP1 will be expressed as below.

Specifically, in FIG. 4, a virtual side surface ISD1 provided by extending the side surface SD2 of the opening OP2 on an upper surface side of the sealing substrate 1S is positioned closer to the side surface OSD1 than the side surface SD1 of the opening OP1. In other words, in FIG. 4, a virtual side surface ISD2 provided by extending the side surface OSD2 of the opening OP2 on an upper surface side of the sealing substrate 1S is positioned closer to the side surface OSD1 than the side surface OSD1 of the opening OP1.

According to this characteristic point according to the first embodiment, for example, due to the configuration as illustrated in FIG. 3, in which a plane size of the opening OP1 is larger than a plane size of the opening OP2, and the opening OP2 is included in the opening OP1, a difference in level is formed at a communicating portion between the opening OP1 and the opening OP2 as illustrated in FIG. 4. Consequently, for example, in a stage before sealing the cavity CAV by the sealing substrate 2S, a solution including a compound of an alkali metal is dropped on an upper surface of the sealing substrate 1S. In this case, the dropped solution tries to creep up on a side surface of the cavity CAV due to surface tension.

However, according to the first embodiment, since the above-described characteristic points are included, a difference in level necessarily formed in a communicating portion between the opening OP1 and the opening OP2 prevents that the dropped solution creeps up on a side surface of the cavity CAV. Therefore, according to the first embodiment, it is prevented that the dropped solution creeps up on a side surface of the cavity CAV and also spills over on a front surface of the substrate member SM. In the case where a solution is dried, this means that it is prevented that a compound is precipitated on a front surface of the substrate member SM from a side surface of the cavity CAV. Then, as a result, according to the first embodiment, the cavity CAV provided on the substrate member SM is sealed by the sealing substrate 2S. In this case, it is prevented that a compound precipitates over a front surface of the substrate member SM from a side surface of the cavity CAV. Accordingly, according to the first embodiment, it is prevented that a compound is inserted between a front surface of the substrate member SM and the sealing substrate 2S. Therefore, in the gas cell GC according to the first embodiment, occurrence of a bonding defect caused by which a compound is inserted between a front surface of the substrate member SM and a lower surface of the sealing substrate 2S is prevented by providing the above-described characteristic points. Therefore, reliability with respect to hermetic sealing of the cavity CAV provided in the gas cell GC can be improved.

Specifically, an essence of the technical idea according to the first embodiment is to form a difference in level functioning as a stopper for blocking that a solution creeps up on a side surface of the cavity CAV by surface tension. As an embodiment for embodying the configuration, in the first embodiment, the cavity CAV is formed by the openings OP1 and OP2 which communicate each other and have a different plane size. According to the configuration, in the first embodiment, a difference in level which functions as a stopper is provided on a side surface of the cavity CAV. The difference in level formed on a side surface of the cavity CAV blocks that a solution creeps up due to surface tension.

Manufacturing Method for Gas Cell According to First Embodiment

The gas cell GC according to the first embodiment is configured as described above, and a manufacturing method therefor will be described below with reference to drawings.

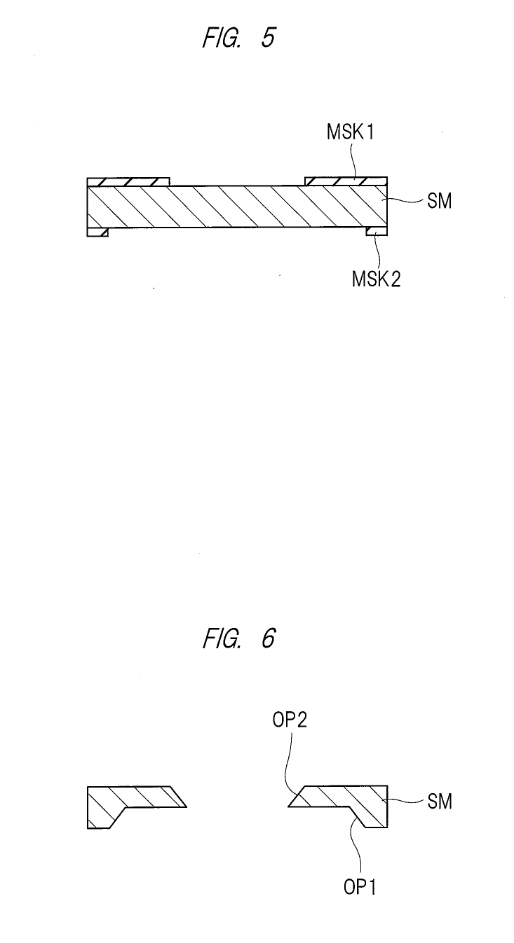

First, as illustrated in FIG. 5, for example, the substrate member SM including a Si substrate is prepared. Then, by using a photolithography technique and an etching technique, a patterned mask film MSK1 is formed on a front surface of the substrate member SM, and a patterned mask film MSK2 is formed on a back surface of the substrate member SM. The mask film MSK1 is patterned so as to expose a region for forming the opening OP2. The mask film MSK2 is patterned so as to expose a region for forming the opening OP1. The mask film MSK1 and the mask film MSK2 are, for example, formed from a silicon oxide film.

Next, as illustrated in FIG. 6, by a both side etching technique in which the patterned mask films MSK1 and MSK2 are used as a mask, the opening OP2 is formed on a front surface side of the substrate member SM, and the opening OP1 is formed on a back surface side of the substrate member SM. Accordingly, a penetration portion is formed on the substrate member SM by the openings OP1 and OP2 communicating each other. At this time, the openings OP1 and OP2 are formed so that a width of the opening OP1 becomes larger than a width of the opening OP2.

An example of the both side etching technique includes a wet etching using such as potassium hydroxide (KOH) solution. In the wet etching, etching can be performed from the both sides of a front surface and a back surface of the substrate member SM at the same time. The openings OP1 and OP2 can be formed on the substrate member SM by performing the wet etching once.

In a process in which the openings OP1 and OP2 are formed on the substrate member SM, the openings are not necessarily formed by the above-described wet etching using the mask films MSK1 and MSK2. For example, the substrate member SM can be machined directly by such as a laser light and a drill. In this case, formation of the mask films MSK1 and MSK2 can be omitted.

Further, as illustrated in FIG. 6, a sectional shape of a side surface of the opening OP1 and a sectional surface of a side surface of the opening OP2 are not necessarily an inclined shape and may be a vertical shape or a curbed surface shape. Furthermore, the openings OP1 and OP2 are formed on the substrate member SM in multiple processes. For example, after dry etching using silicon tetrafluoride (SiF₄) gas is performed from a front surface side of the substrate member SM for one hour, a process can be applied in which dry etching is similarly performed so as to penetrate the substrate member SM from a back surface side of the substrate member SM.

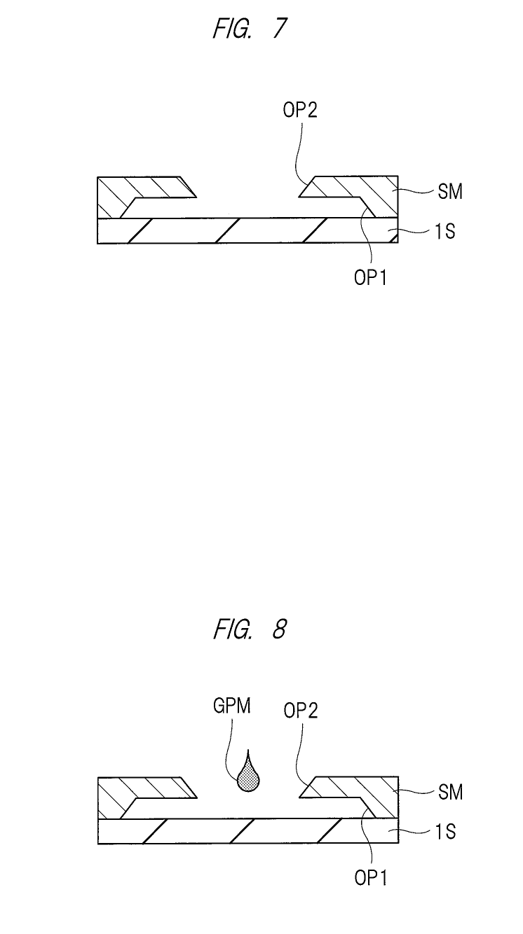

Next, as illustrated in FIG. 7, the sealing substrate 1S is bonded on a back surface of the substrate member SM. Accordingly, the opening OP1 formed on the substrate member SM comes into contact with an upper surface of the sealing substrate 1S. For example, in the case where a Si substrate is used as the substrate member SM, and a borosilicate glass substrate is used as the sealing substrate 1S, the substrate member SM and the sealing substrate 1S can be bonded by anode bonding. If sealability between the substrate member SM and the sealing substrate 1S is ensured, the substrate member SM and the sealing substrate 1S may be bonded by other methods. For example, the substrate member SM and the sealing substrate 1S may be bonded by using an adhesive.

Next, as illustrated in FIG. 8, for example, a gas production material GPM including a solution of a compound including an alkali metal such as cesium azide (CsN₃) is dropped on an upper surface of the sealing substrate 1S in the opening OP1. A micropipette and a dispenser can be used to drop the gas production material GPM in a liquid state.

In the first embodiment, as illustrated in FIG. 8, a width of the opening OP1 is larger than a width of the opening OP2, and the opening OP2 is included in the opening OP1. A difference in level is formed on a communicating portion between the openings OP1 and OP2. As this result, it is prevented by the difference in level formed in the communicating portion between the openings OP1 and OP2 that the dropped gas production material GPM creeps up on side surfaces of the openings OP1 and OP2. Therefore, according to the first embodiment, it is prevented that the dropped gas production material GPM in a liquid state creeps up on side surfaces of the openings OP1 and OP2 and also spills over on a front surface of the substrate member SM. Specifically, according to the first embodiment, it is prevented that the dropped gas production material GPM in a liquid state spills over on a front surface of the substrate member SM due to surface tension and differences in hydrophobicity and hydrophilicity between the substrate member SM and the sealing substrate 1S.

The gas production material GPM in a liquid state may include, for example, a compound which produces a gas other than an alkali metal such as a nitrogen gas like barium azide (BaN₆) and other materials such as liquid paraffin, in addition to a compound including an alkali metal.

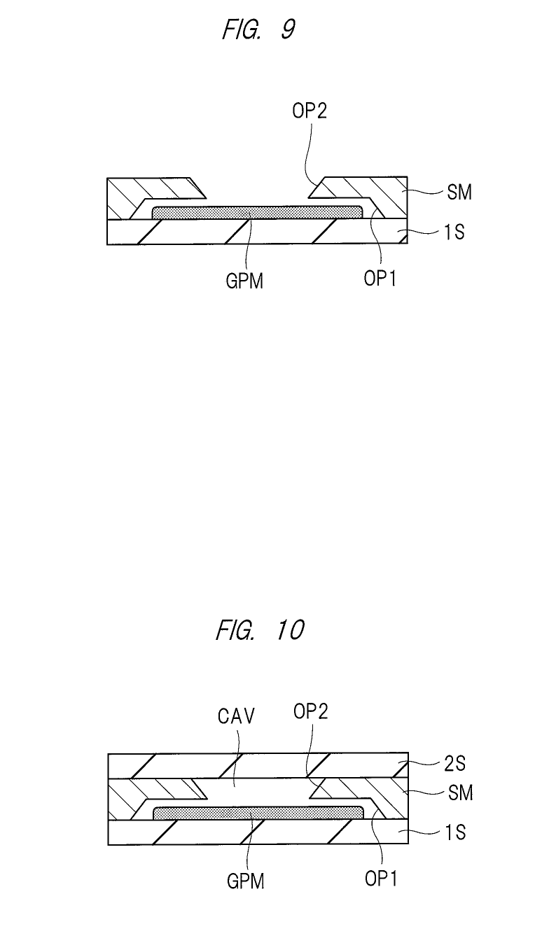

Next, as illustrated in FIG. 9, the gas production material GPM in a liquid state is dried by heating the gas production material GPM in a liquid state. Accordingly, the gas production material GPM in a solid state is precipitated on an upper surface of the sealing substrate 1S in the opening OP1. In this heating process, for example, a hot plate is inserted on a lower side of the sealing substrate 1S, and the sealing substrate 1S is sufficiently heated at a temperature equal to or higher than a boiling point of a solvent. In the first embodiment, since a difference in level is provided at a communicating portion between the openings OP1 and OP2, it is prevented that, when a solvent is dried, the gas production material GPM in a solid state creeps up on side surfaces of the openings OP1 and OP2 and also rises up to a front surface of the substrate member SM due to surface tension.

In the first embodiment, as illustrated in FIGS. 8 and 9, after the gas production material GPM in a liquid state is dropped on an upper surface of the sealing substrate 1S in the opening OP1, the dropped gas production material GPM in a liquid state is heated. However, it is not limited thereto, for example, the gas production material GPM in a liquid state may be dropped in a state in which the sealing substrate 1S is heated.

Next, as illustrated in FIG. 10, the sealing substrate 2S is bonded on a front surface of the substrate member SM. Further in this process, for example, in the case where a Si substrate is used as the substrate member SM, and a borosilicate glass substrate is used as the sealing substrate 2S, the substrate member SM and the sealing substrate 2S can be bonded by anode bonding. Accordingly, the cavity CAV including the openings OP1 and OP2 are hermetically sealed by the sealing substrates 1S and 2S.

At this time, a process for sealing the cavity CAV provided on the substrate member SM by the sealing substrate 2S may be performed in an atmosphere such as a nitrogen gas and a rare gas so that the nitrogen gas and the rare gas are sealed in the cavity CAV. The nitrogen gas and the rare gas include a function to prevent disturbance of the spin polarization of an alkali metal gas.

In the first embodiment, as described above, since a difference in level is formed on a communication portion between the openings OP1 and OP2, it is prevented that the dropped gas production material GPM in a liquid state creeps up on a side surface of the cavity CAV and also spills over on a front surface of the substrate member SM. Further, in a process for drying the gas production material GPM, it is prevented that the gas production material GPM adheres on a front surface of the substrate member SM.

As this result, according to the first embodiment, a bonding defect between the substrate member SM and the sealing substrate 2S can be prevented which is caused when a compound is inserted between the substrate member SM and the sealing substrate 2S. Accordingly, in the first embodiment, a manufacturing yield of a gas cell can be improved.

After the cavity CAV is sealed, an alkali metal gas and a nitrogen gas are produced from the gas production material GPM by causing a photodecomposition reaction and a thermal decomposition reaction with respect to the gas production material GPM existing on an upper surface of the sealing substrate 1S in the cavity CAV. Accordingly, an alkali metal gas and a nitrogen gas are filled in the cavity CAV.

As described above, a gas cell in the magnetic field measuring apparatus according to the first embodiment can be manufactured. In the first embodiment, a single gas cell is described as an example. However, multiple gas cells may be formed on a wafer, and a single gas cell may be cut as needed.

### Second Embodiment

In the first embodiment, an example in which the openings OP1 and 0P2 are formed on the substrate member SM has been described. In a second embodiment, an example will be described in which a first substrate member and a second substrate member, which is different from the first substrate member, are provided, and an opening OP1 is formed on the first substrate member, and an opening OP2 is formed on the second substrate member. A gas cell GC according to the second embodiment has almost the same configuration as the gas cell GC according to the first embodiment.

Configuration of Gas Cell According to Second Embodiment

FIG. 11 is an enlarged plan view illustrating a sealing region SLR of the gas cell GC according to the second embodiment. In FIG. 11, for example, a rectangular opening OP1 and a square opening OP2 are provided in the sealing region SLR of the gas cell GC according to the second embodiment. A cavity CAV is formed by the openings OP1 and OP2.

As illustrated in FIG. 11, in short sides and long sides forming the rectangular shape of the opening OP1, a length of the short sides is equal to sides forming the square shape of the opening OP2. Therefore, the long sides forming the rectangular shape of the opening OP1 are longer than the sides forming the square shape of the opening OP2. Consequently, as illustrated in FIG. 11, a plane size of the opening OP1 is larger than a plane size of the opening OP2. In plan view, the opening OP2 is included in the opening OP1.

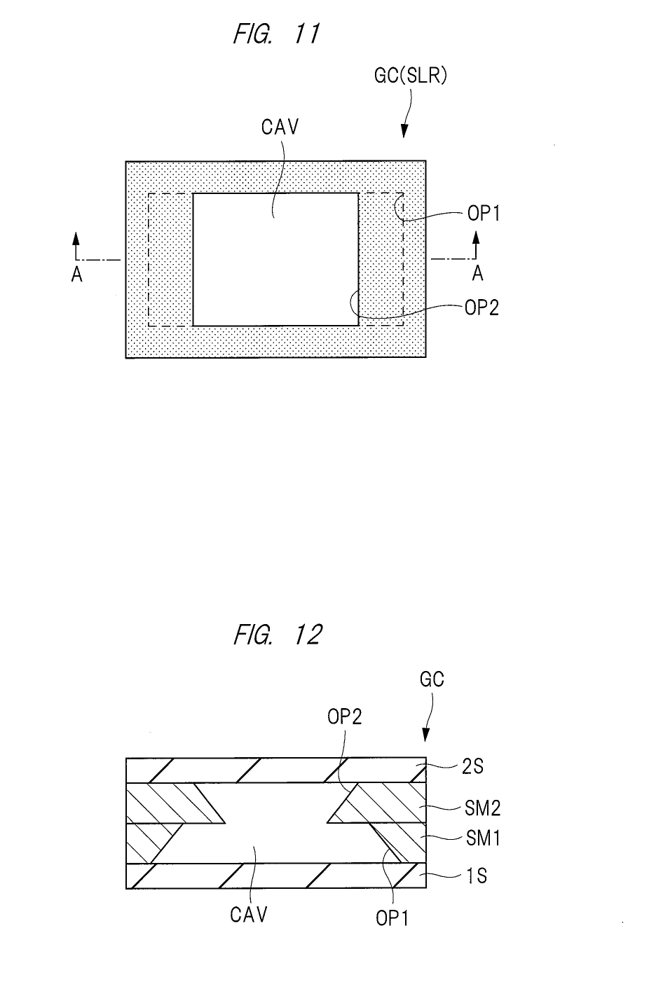

Next, FIG. 12 is a sectional view cut on line A-A illustrated in FIG. 11. As illustrated in FIG. 12, the gas cell GC according to the second embodiment includes a substrate member SM1 and a substrate member SM2 disposed on the substrate member SM1. The opening OP1 is formed on the substrate member SM1, and the opening OP2 is formed on the substrate member SM2. A cavity CAV is formed by the openings OP1 and OP2. Specifically, the cavity CAV includes the opening OP1 coming into contact with an upper surface of a sealing substrate 1S and the opening OP2 coming into contact with a lower surface of a sealing substrate 2S. The openings OP1 and OP2 communicate in a thickness direction. As illustrated in FIG. 12, in the second embodiment, a width of the opening OP1 formed on the substrate member SM1 is larger than a width of the opening OP2 formed on the substrate member SM2.

In the second embodiment as described above, for example, due to a configuration as illustrated in FIG. 11, in which a plane size of the opening OP1 is larger than a plane size of the opening OP2, and the opening OP2 is included in the opening OP1, a difference in level is formed at a communicating portion between the opening OP1 and the opening OP2 as illustrated in FIG. 12. Consequently, also in the second embodiment, it is prevented by the difference in level that a dropped solution creeps up on a side surface of the cavity CAV. Therefore, according to the second embodiment, it is prevented that the dropped solution creeps up on a side surface of the cavity CAV and also spills over on a front surface of the substrate member SM.

Accordingly, also in the second embodiment, it is prevented that a compound is precipitated on a front surface of the substrate member SM from a side surface of the cavity CAV. Consequently, also in the second embodiment, it is prevented that a compound is inserted between a front surface of the substrate member SM and the sealing substrate 2S. Therefore, in the gas cell GC according to the second embodiment, occurrence of a bonding defect can be prevented which is caused by which a compound is inserted between a front surface of the substrate member SM and a lower surface of the sealing substrate 2S. Therefore, reliability with respect to hermetic sealing of the cavity CAV provided in the gas cell GC can be improved.

Especially, in the second embodiment, the opening OP1 and the opening OP2 are formed on a separate substrate member. Specifically, in the second embodiment, as illustrated in FIG. 12, the opening OP1 is formed on the substrate member SM1, and the opening OP2 is formed on the substrate member SM2. As described above, in the second embodiment, the substrate member SM1 and the substrate member SM2 are laminated, and therefore, in comparison with the first embodiment in which a single layered substrate member SM is used, a thickness of the substrate member (the substrate member SM1+the substrate member SM2) sandwiched between the sealing substrate 1S and the sealing substrate 2S becomes thick. This means that a thickness of the cavity CAV according to the second embodiment becomes thicker than a thickness of the cavity CAV according to the first embodiment. Therefore, in the second embodiment, an optical path length in the cavity CAV of an irradiation light used to measure a magnetic field becomes long. Thus, according to a magnetic field measuring apparatus using the gas cell GC according to the second embodiment, a number of alkali metal atoms in the cavity CAV, which interact with an irradiation light, is increased. Therefore, measurement sensitivity of a magnetic field is improved. Specifically, the gas cell GC according to the second embodiment is superior to the gas cell GC according to the first embodiment in terms of improvement of measurement sensitivity of a magnetic field.

Manufacturing Method for Gas Cell According to Second Embodiment

The gas cell GC according to the second embodiment is configured as described above, and a manufacturing method therefor will be described below with reference to drawings.

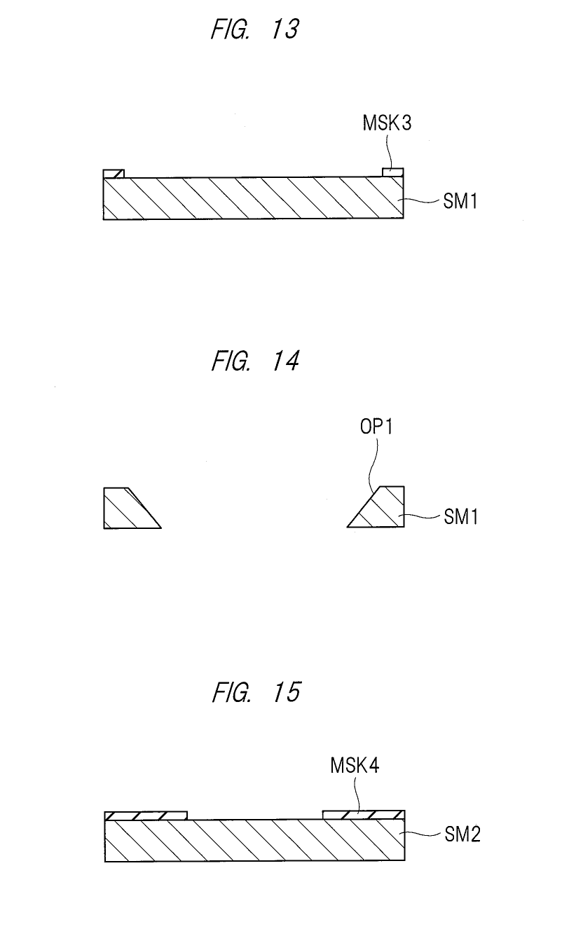

First, as illustrated in FIG. 13, for example, the substrate member SM1 including a Si substrate is prepared. Then, by using a photolithography technique and an etching technique, a patterned mask film MSK3 is formed on a front surface of the substrate member SM1. The mask film MSK3 is patterned so as to expose a region for forming the opening OP1. The mask film MSK3 is, for example, formed of a silicon oxide film.

Next, as illustrated in FIG. 14, by the etching technique in which the patterned mask films MSK3 is used as a mask, the opening OP1 is formed on the substrate member SM1. At this time, the opening OP1 formed on the substrate member SM1 is formed so as to penetrate the substrate member SM1.

Next, as illustrated in FIG. 15, for example, the substrate member SM2 including a Si substrate is prepared. Then, by using a photolithography technique and an etching technique, a patterned mask film MSK4 is formed on a front surface of the substrate member SM2. The mask film MSK4 is patterned so as to expose a region for forming the opening OP2. The mask film MSK4 is, for example, formed of a silicon oxide film.

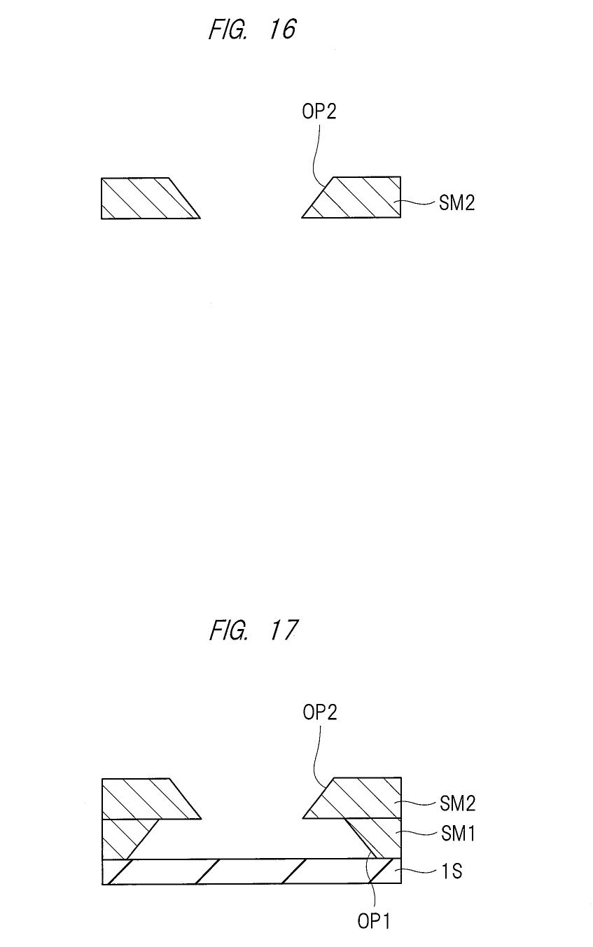

Next, as illustrated in FIG. 16, by the etching technique in which the patterned mask film MSK4 is used as a mask, the opening OP2 is formed on the substrate member SM2. At this time, the opening OP2 formed on the substrate member SM2 is formed so as to penetrate the substrate member SM2.

In the second embodiment as described above, the substrate member SM1 and the substrate member SM2 are separately prepared, the opening OP1 is formed so as to penetrate the substrate member SM1, and the opening OP2 is formed so as to penetrate the substrate member SM2. Therefore, in a manufacturing method for the gas cell GC according to the second embodiment, in a relatively easy process, the opening OP1 is formed on the substrate member SM1, and also the opening OP2 is formed on the substrate member SM2.

In terms of this point, in the above-described first embodiment, it has been necessary to form the openings OP1 and OP2 having different widths from a both sides of one substrate member SM, and a complicated manufacturing process has been needed. On the other hand, in the second embodiment, although the substrate member SM1 and the substrate member SM2, which are separately disposed, are needed to be prepared, a process to form a single opening OP1 on the substrate member SM1 and a process to form a single opening OP2 on the substrate member SM2 are relatively simple in comparison with the process according to the first embodiment. Consequently, a difficulty level in a manufacturing process for the gas cell GC according to the second embodiment is lower than that of a manufacturing process for the gas cell according to the first embodiment. Accordingly, a manufacturing yield can be improved. Specifically, in terms of improving the manufacturing yield of the gas cell GC, the manufacturing process for the gas cell GC according to the second embodiment is superior to the manufacturing process for the gas cell GC according to the first embodiment.

Next, as illustrated in FIG. 17, the substrate member SM1 in which the opening OP1 is formed and the substrate member SM2 in which the opening OP2 is formed are bonded. At this time, for example, in the case where both of the substrate members SM1 and SM2 include a Si substrate, the substrates are bonded by thermal bonding. Further, the sealing substrate 1S is bonded on a back surface of the substrate member SM1. Accordingly, the opening OP1 formed on the substrate member SM1 comes into contact with an upper surface of the sealing substrate 1S. For example, in the case where a Si substrate is used as the substrate member SM1, and a borosilicate glass substrate is used as the sealing substrate 1S, the substrate member SM1 and the sealing substrate 1S can be bonded by anode bonding. If sealability between the substrate member SM1 and the sealing substrate 1S is ensured, the substrate member SM1 and the sealing substrate 1S may be bonded by other methods. For example, the substrate member SM1 and the sealing substrate 1S may be bonded by using an adhesive.

For example, as illustrated in FIG. 17, in the case where the substrate member SM1 and the substrate member SM2 are bonded, the substrates are preferably bonded each other on surfaces having a narrow opening width. This is because, in this case, as illustrated in FIG. 17, an angle between the opening OP1 formed on the substrate member SM1 and an upper surface of the sealing substrate 1S can be set to an acute angle, and accordingly creep-up of a solution to be dropped in a subsequent process on a side surface of the cavity CAV can be easily prevented.

Next, as illustrated in FIG. 18, for example, a gas production material GPM including a solution of a compound including an alkali metal such as cesium azide (CsN3) is dropped on an upper surface of the sealing substrate 1S in the opening OP1. A micropipette and a dispenser can be used to drop the gas production material GPM in a liquid state.

In the second embodiment, as illustrated in FIG. 18, a width of the opening OP1 is larger than a width of the opening OP2, and the opening OP2 is included in the opening OP1. A difference in level is formed on a communicating portion between the openings OP1 and OP2. As this result, it is prevented by the difference in level formed in the communicating portion between the openings OP1 and OP2 that the dropped gas production material GPM creeps up on side surfaces of the openings OP1 and OP2. Therefore, according to the second embodiment, it is prevented that the dropped gas production material GPM in a liquid state creeps up on side surfaces of the openings OP1 and OP2 and also spills over on a front surface of the substrate member SM.

Next, the gas production material GPM in a liquid state is dried by heating the gas production material GPM in a liquid state. Accordingly, the gas production material GPM in a solid state is precipitated on an upper surface of the sealing substrate 1S in the opening OP1.

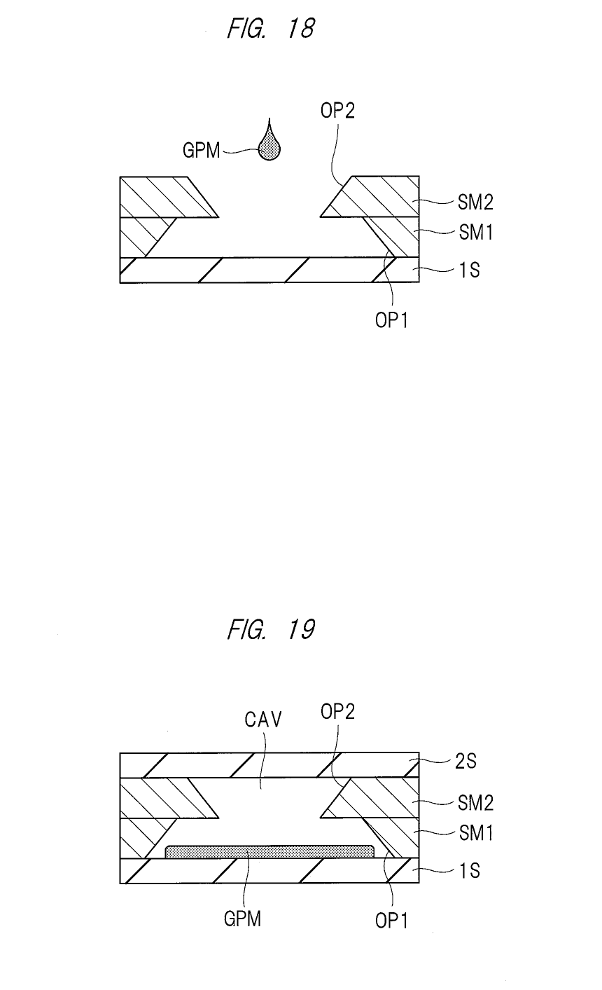

Next, as illustrated in FIG. 19, the sealing substrate 2S is bonded on a front surface of the substrate member SM2. Further in this process, for example, in the case where a Si substrate is used as the substrate member SM2, and a borosilicate glass substrate is used as the sealing substrate 2S, the substrate member SM and the sealing substrate 2S can be bonded by anode bonding. Accordingly, the cavity CAV including the openings OP1 and OP2 are hermetically sealed by the sealing substrates 1S and 2S.

In the second embodiment, as described above, since a difference in level is formed on a communication portion between the openings OP1 and OP2, it is prevented that the dropped gas production material GPM in a liquid state creeps up on a side surface of the cavity CAV and also spills over on a front surface of the substrate member SM2. Further, in a process for drying the gas production material GPM, it is prevented that the gas production material GPM adheres on a front surface of the substrate member SM2.

As this result, according to the second embodiment, a bonding defect between the substrate member SM2 and the sealing substrate 2S can be prevented which is caused when a compound is inserted between the substrate member SM2 and the sealing substrate 2S. Accordingly, a manufacturing yield of a gas cell can be improved.

After the cavity CAV is sealed, an alkali metal gas and a nitrogen gas are produced from the gas production material GPM by causing a photodecomposition reaction and a thermal decomposition reaction with respect to the gas production material GPM existing on an upper surface of the sealing substrate 1S in the cavity CAV. Accordingly, an alkali metal gas and a nitrogen gas are filled in the cavity CAV. As described above, a gas cell of the magnetic field measuring apparatus according to the second embodiment can be manufactured.

### Third Embodiment

In the third embodiment, an example will be described in which, in openings OP1 and OP2 forming a cavity CAV of a gas cell GC, a depth of the opening OP1 having a larger plane size is equal to or less than 1 mm. A gas cell GC according to the third embodiment has almost the same configuration as the gas cell GC according to the first embodiment.

Configuration of Gas Cell According to Third Embodiment

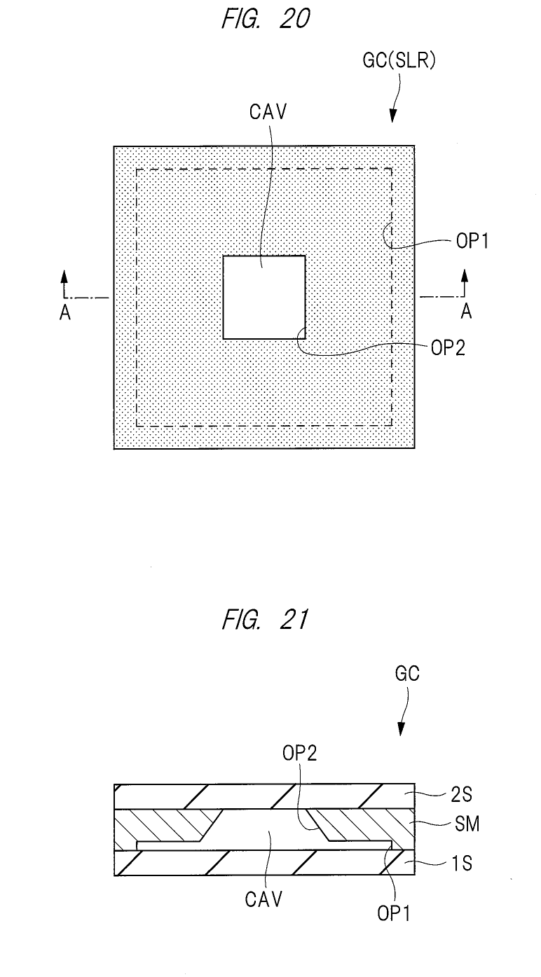

FIG. 20 is an enlarged plan view illustrating a sealing region SLR of the gas cell GC according to the third embodiment. In FIG. 20, for example, the square opening OP1 and the square opening OP2 are provided in the sealing region SLR of the gas cell GC according to the third embodiment. The cavity CAV is formed by the openings OP1 and OP2. As illustrated in FIG. 20, a plane size of the opening OP1 is larger than a plane size of the opening OP2. In plan view, the opening OP2 is included in the opening OP1.

Next, FIG. 21 is a sectional view cut on line A-A illustrated in FIG. 20. As illustrated in FIG. 21, the gas cell GC according to the third embodiment includes a substrate member SM, and the openings OP1 and OP2 are formed on the substrate member SM. The cavity CAV is formed by the openings OP1 and OP2. Specifically, the cavity CAV includes the opening OP1 coming into contact with an upper surface of a sealing substrate 1S and the opening OP2 coming into contact with a lower surface of a sealing substrate 2S. The openings OP1 and OP2 communicate in a thickness direction. As illustrated in FIG. 21, according to the third embodiment, a width of the opening OP1 is larger than a width of the opening OP2. The third embodiment is characterized in that a depth of the opening OP1 (length in a thickness direction) is equal to or less than 1 mm. This characteristic brings an advantage in the third embodiment. The advantage in this characteristic will be described in a manufacturing method for a gas cell to be described below.

Characteristics of Gas Cell According to Third Embodiment

The gas cell GC according to the third embodiment is configured as described above, and a manufacturing method therefor will be described below with reference to drawings.

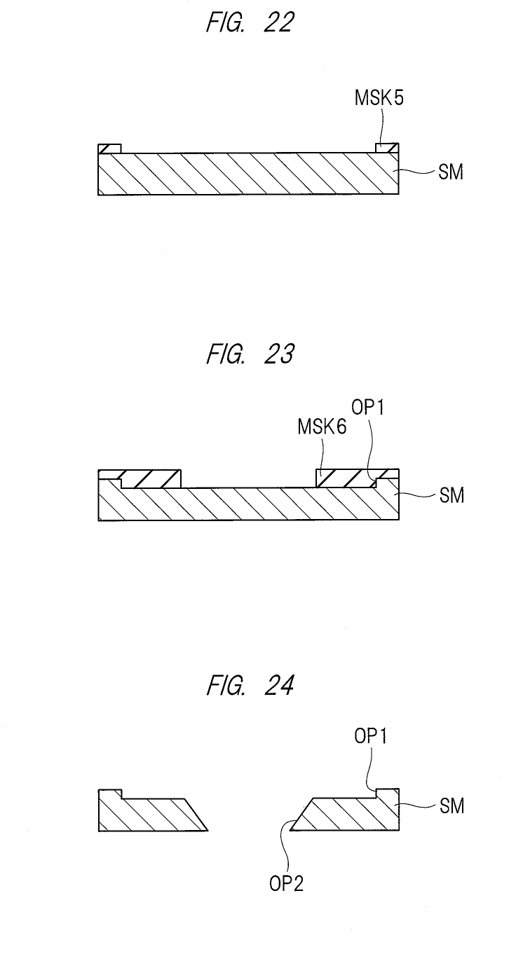

First, as illustrated in FIG. 22, for example, the substrate member SM including a Si substrate is prepared. Then, by using a photolithography technique and an etching technique, a patterned mask film MSK5 is formed on a front surface of the substrate member SM. The mask film MSK5 is patterned so as to expose a region for forming the opening OP1. The mask film MSK5 is, for example, formed of a silicon oxide film.

Next, as illustrated in FIG. 23, the mask film MSK5 is formed on a front surface of the substrate member SM, and a recessed opening OP1 is formed on the front surface of the substrate member SM by the etching technique in which the mask film MSK5 is used as a mask. At this time, a depth of the opening OP1 is equal to or less than 1 mm.

FIG. 23 illustrates an example in which a sectional surface of the opening OP1 has a right angle on the assumption that anisotropic etching is applied. However, an etching method is not limited as long as a thickness of the opening OP1 can be adjusted to 1 mm or less in the method.

Next, after the patterned mask film MSK5 is removed, a patterned mask film MSK6 is formed on a front surface of the substrate member SM in which the opening OP1 is formed by using a photolithography technique and an etching technique. The mask film MSK6 is patterned so as to expose a region for forming the opening OP2 of which width is narrower than a width of the opening OP1. The mask film MSK6 is, for example, formed of a silicon oxide film.

Then, as illustrated in FIG. 24, the opening OP2 penetrating the substrate member SM is formed by etching in which the mask film MSK6 formed on a front surface of the substrate member SM is used as a mask. Accordingly, the openings OP1 and OP2 having different widths are formed on the substrate member SM.

In the third embodiment, as illustrated in FIG. 23, an example is described in which the mask film MSK6 is formed on a front surface of the substrate member SM in which the opening OP1 is formed. However, it is not limited thereto, and the mask film MSK6 can be formed on a back surface opposite to the front surface in which the opening OP1 is formed, and the opening OP2 can be formed by etching from the back surface of the substrate member SM. Further, the substrate member SM may be directly machined by such as a laser and a drill, not by an etching technique. In this case, formation of the mask film MSK6 can be omitted.

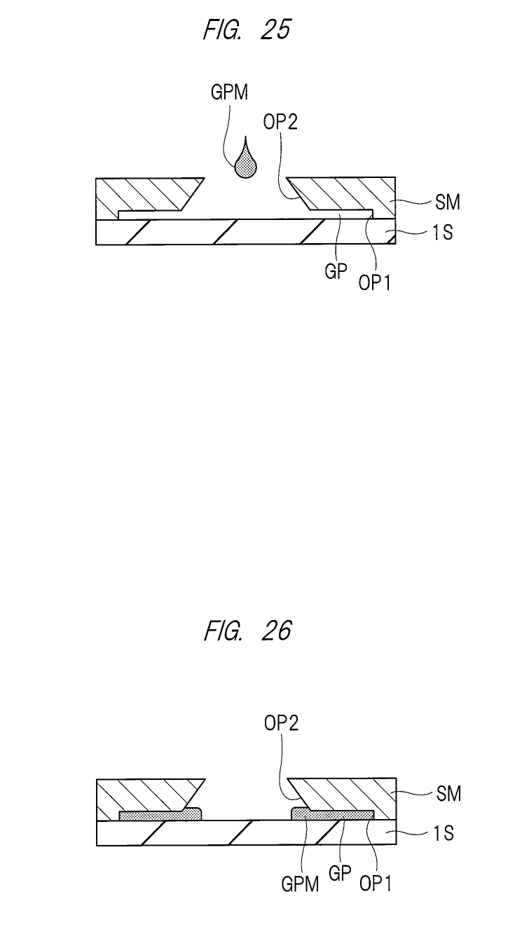

Next, as illustrated in FIG. 25, the substrate member SM and the sealing substrate 1S are bonded so as to face a front surface of the substrate member SM in which the opening OP1 is formed and an upper surface of the sealing substrate 1S by turning the substrate member SM upside down. For example, in the case where a Si substrate is used as the substrate member SM, and a borosilicate glass substrate is used as the sealing substrate 1S, the substrate member SM and the sealing substrate 1S can be bonded by anode bonding. If sealability between the substrate member SM and the sealing substrate 1S is ensured, the substrate member SM and the sealing substrate 1S may be bonded by other methods. For example, the substrate member SM and the sealing substrate 1S may be bonded by using an adhesive.

Next, for example, a gas production material GPM including a solution of a compound including an alkali metal such as cesium azide (CsN3) is dropped on an upper surface of the sealing substrate 1S in the opening OP1. A micropipette and a dispenser can be used to drop the gas production material GPM in a liquid state. At this time, as illustrated in FIG. 26, the dropped gas production material GPM in a liquid state is sucked in a small gap GP by the opening OP1 by capillary phenomenon. Specifically, in the third embodiment, since a depth of the opening OP1 is 1 mm or less, the small gap GP by the opening OP1 is formed. The gas production material GPM in a liquid state is soaked in this small gap GP. Consequently, according to the third embodiment, the gas production material GPM exists locally in the small gap GP by the opening OP1.

Thus, in the third embodiment, since the gas production material GPM is soaked in the small gap GP, it is prevented that the dropped gas production material GPM creeps up on a side surface of the opening OP2. Therefore, according to the third embodiment, it is prevented that the dropped gas production material GPM in a liquid state creeps up on a side surface of the openings OP2 and also spills over on a front surface of the substrate member SM.

Then, the gas production material GPM in a liquid state is dried by heating the gas production material GPM in a liquid state. Accordingly, the gas production material GPM in a solid state is precipitated in the small gap GP by the opening OP1.

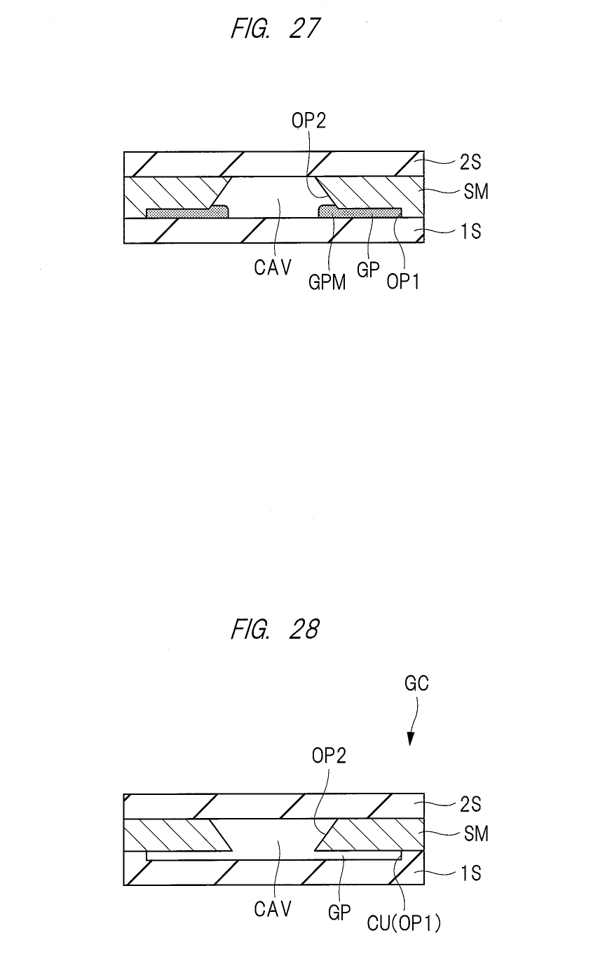

Next, as illustrated in FIG. 27, the sealing substrate 2S is bonded on a front surface of the substrate member SM. Further in this process, for example, in the case where a Si substrate is used as the substrate member SM, and a borosilicate glass substrate is used as the sealing substrate 2S, the substrate member SM and the sealing substrate 2S can be bonded by anode bonding. Accordingly, the cavity CAV including the openings OP1 and OP2 are hermetically sealed by the sealing substrates 1S and 2S.

In the third embodiment, mainly the gas production material GPM is soaked in the small gap GP by capillary phenomenon, and therefore it is prevented that the dropped gas production material GPM in a liquid state creeps up on a side surface of the cavity CAV and also spills over on a front surface of the substrate member SM. Further, in a process for drying the gas production material GPM, it is prevented that the gas production material GPM adheres on a front surface of the substrate member SM.

As this result, according to the third embodiment, a bonding defect between the substrate member SM and the sealing substrate 2S can be prevented which is caused when a compound is inserted between the substrate member SM and the sealing substrate 2S. Accordingly, a manufacturing yield of a gas cell can be improved.

After the cavity CAV is sealed, an alkali metal gas and a nitrogen gas are produced from the gas production material GPM by causing a photodecomposition reaction and a thermal decomposition reaction with respect to the gas production material GPM existing locally in the gap GP. Accordingly, an alkali metal gas and a nitrogen gas are filled in the cavity CAV. In the case where an alkali metal gas is produced from the gas production material GPM by a photodecomposition reaction, a light used in the photodecomposition reaction is emitted from a lower surface (back surface) side of the sealing substrate 1S.

As described above, a gas cell of the magnetic field measuring apparatus according to the second embodiment can be manufactured. Especially, in the third embodiment, as illustrated in FIG. 27, since the gas production material GPM in a solid state exists locally in the gap GP by the opening OP1, the gas production material GPM is not easily remained at a center portion of the cavity CAV which is a passing area of a laser light. Therefore, according to the third embodiment, when a laser light (pumping light) used for measuring a magnetic field passes the cavity CAV of a gas cell, the gas production material GPM in a solid state prevents that the laser light is reflected or absorbed.

Variation

Next, a variation of the third embodiment will be described. FIG. 28 is a sectional view illustrating a configuration of a gas cell GC according to the variation. In the variation in FIG. 28, a groove CU is formed on an upper surface of the sealing substrate 1S, the groove CU functions as an opening OP1. An opening OP2 is formed on a substrate member SM. Therefore, in the variation, the cavity CAV is formed from the groove CU (opening OP1) formed on the sealing substrate 1S and the opening OP2 formed on the substrate member SM.

In the gas cell GC according to the variation, the groove CU (recessed portion) is formed on an upper surface of the sealing substrate 1S, and the opening OP1 is formed from the groove CU. At this time, a depth of the groove CU formed on the sealing substrate 1S is equal to or less than 1 mm.

In the variation, as with the third embodiment, since a gas production material GPM is soaked in a small gap GP, it is prevented that the dropped gas production material GPM creeps up on a side surface of the opening OP2. As this result, according to the variation, it is prevented that the dropped gas production material GPM in a liquid state creeps up on a side surface of the openings OP2 and also spills over on a front surface of the substrate member SM. Further, in the variation, as with the third embodiment, since the gas production material GPM in a solid state can exist locally in the gap GP by the groove CU (opening OP1), it is prevented that a laser light passing through the cavity CAV is reflected or absorbed.

In the variation, the groove CU is formed on the sealing substrate 1S, and the opening OP2 is formed on the substrate member SM. Thus, a process for etching both sides by forming mask films on both sides of the substrate member SM as in the first embodiment and a process for forming the openings OP1 and OP2 on the substrate member SM by using a photolithography technique and an etching technique twice as in the third embodiment are not needed. Specifically, a manufacturing process for the substrate member SM according to the variation can be simplified in comparison with the processes in the first embodiment and the third embodiment. Further, in the variation, the opening OP2 is formed on the substrate member SM, and the opening OP1 is formed on the sealing substrate 1S. Therefore, machining can be easily adjusted in comparison with the case where the openings OP1 and OP2 are formed on the same substrate member SM.

### Fourth Embodiment

In the first to third embodiments, an example has been described in which one cavity CAV has been formed in one gas cell GC. However, in a fourth embodiment, an example will be described in which cavities CAV1 and CAV2 are formed in one gas cell GC.

For example, in a configuration example in which one cavity CAV is formed in one gas cell GC, in the case where a gas production material GPM in a solid state is remained in the cavity CAV, the gas production material GPM in a solid state might disturb a laser light passing through the cavity CAV. In the fourth embodiment, cavities CAV1 and CAV2 are provided in one gas cell GC. The cavity CAV1 in which the gas production material GPM in a solid state is remained and the cavity CAV2 through which a laser light passes are separately disposed. The gas cell GC according to the fourth embodiment including the above configuration will be described below with reference to drawings.

Configuration of Gas Cell According to Fourth Embodiment

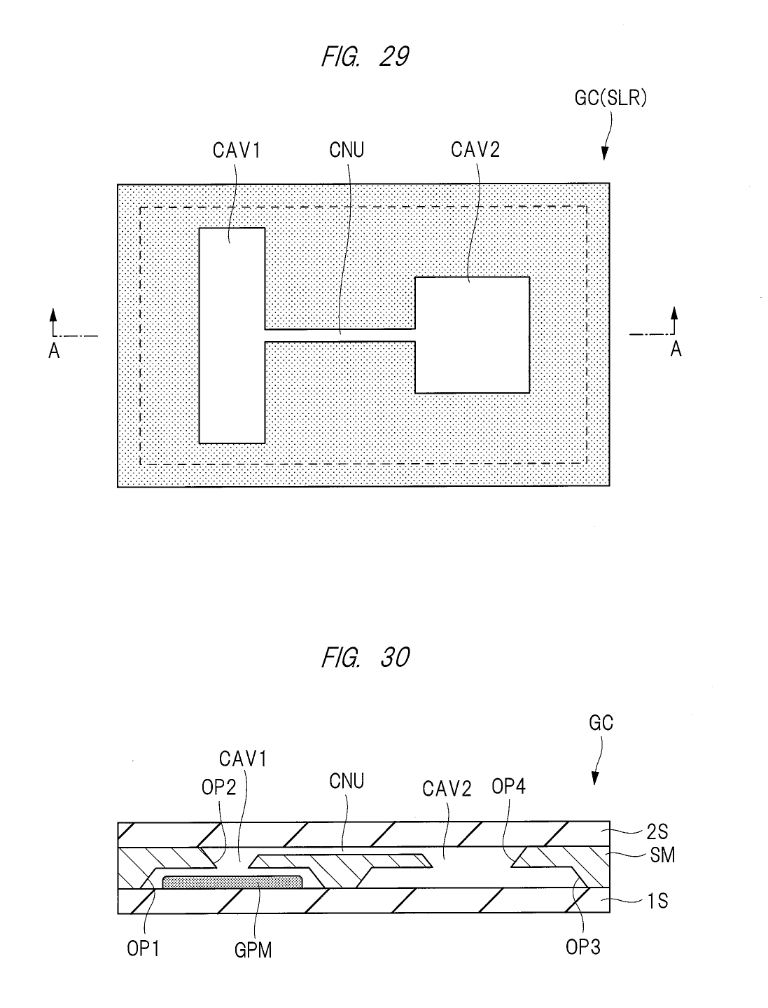

FIG. 29 is an enlarged plan view illustrating a sealing region SLR of the gas cell GC according to the fourth embodiment. In FIG. 29, the gas cell GC according to the fourth embodiment includes the cavities CAV1 and CAV2. The cavities CAV1 and CAV2 are connected to each other through the communication path CNU.

FIG. 30 is a sectional view cut on line A-A illustrated in FIG. 29. As illustrated in FIG. 30, a substrate member SM is provided so as to be sandwiched between a sealing substrate 1S and a sealing substrate 2S. The cavity CAV1, the cavity CAV2, and a communication path CNU connecting the cavity CAV1 and the cavity CAV2 are formed on this substrate member SM. For example, the cavity CAV1 includes an opening OP1 coming into contact with an upper surface of the sealing substrate 1S and the opening OP2 coming into contact with a lower surface of the sealing substrate 2S. The openings OP1 and OP2 communicate in a thickness direction. As illustrated in FIG. 30, according to the fourth embodiment, a width of the opening OP1 is larger than a width of the opening OP2. Similarly, the cavity CAV2 includes the opening OP3 coming into contact with an upper surface of the sealing substrate 1S and the opening OP4 coming into contact with a lower surface of the sealing substrate 2S. The openings OP3 and OP4 communicate in a thickness direction. As illustrated in FIG. 30, according to the fourth embodiment, a width of the opening OP3 is larger than a width of the opening OP4.

In the fourth embodiment, the cavity CAV2 includes the openings OP3 and OP4, but are not limited to, and the cavity CAV2 may include a single opening. Specifically, in the fourth embodiment, at least, the cavity CAV1 includes the openings OP1 and OP2, and the cavity CAV2 can have an arbitrary shape.

In the fourth embodiment, the gas production material GPM in a solid state exists in the cavity CAV1, and the gas production material GPM does not exist in the cavity CAV2. Specifically, the gas production material GPM which produces an alkali metal gas exists on an upper surface of the sealing substrate 1S in the cavity CAV1, and the gas production material GPM does not exist on an upper surface of the sealing substrate 1S in the cavity CAV2. However, a space in the cavity CAV1 and a space of the cavity CAV2 are connected through the communication path CNU, and therefore, an alkali metal gas produced by the gas production material GPM existing in the cavity CAV1 exists also in the cavity CAV2 through the communication path CNU. Specifically, in the gas cell GC according to the fourth embodiment, an alkali metal gas is filled in both of the cavities CAV1 and CAV2.

In the fourth embodiment, a laser light used for measuring a magnetic field passes through the cavity CAV2. Accordingly, since the gas production material GPM in a solid state does not exist in the cavity CAV2, it is prevented that a laser light is reflected and absorbed by the gas production material GPM in a solid state when the laser light passes through the cavity CAV2 of the gas cell GC.

Specifically, a basic concept of the fourth embodiment is that the cavity CAV1 in which the gas production material GPM is disposed and the cavity CAV2 through which a laser light used for measuring a magnetic field passes are separately disposed, and the cavity CAV2 as well as the cavity CAV1 can be filled with an alkali metal gas by spacially communicating the cavities CAV1 and CAV2. Accordingly, even if the gas production material GPM is not disposed in the cavity CAV2, an alkali metal gas can be filled in the cavity CAV2, and an adverse effect by the gas production material GPM in a solid state can be removed by causing a laser light to pass through the cavity CAV2. Consequently, in a magnetic field measuring apparatus using the gas cell GC according to the fourth embodiment, performance including magnetic field measurement accuracy can be improved.

Characteristics of Gas Cell According to Fourth Embodiment

The gas cell GC according to the fourth embodiment is configured as described above, and a manufacturing method therefor will be described below with reference to drawings.

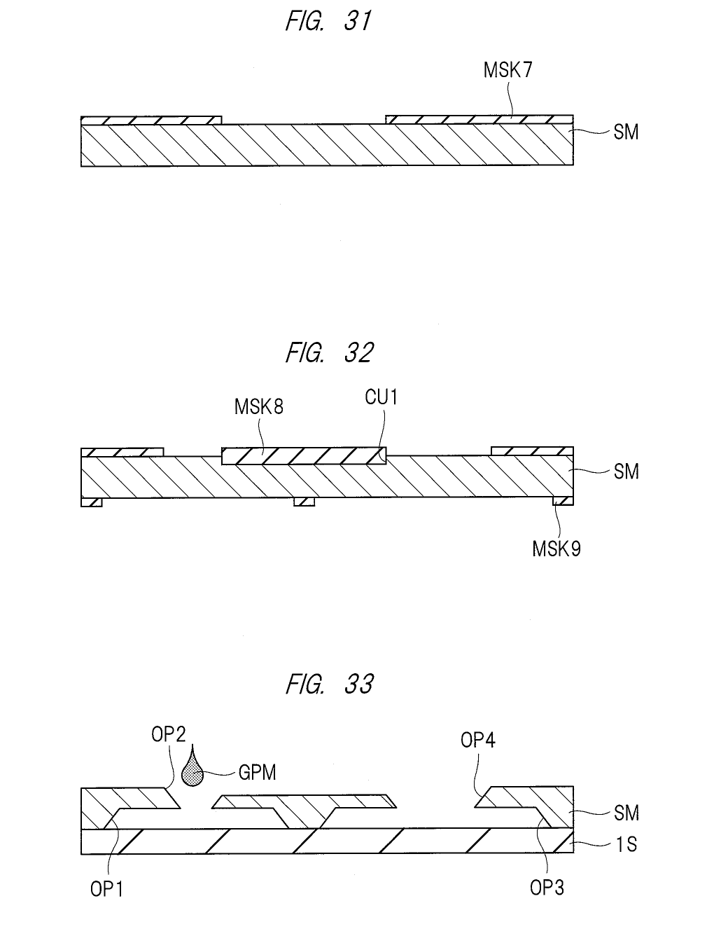

First, as illustrated in FIG. 31, for example, the substrate member SM including a Si substrate is prepared. Then, by using a photolithography technique and an etching technique, a patterned mask film MSK7 is formed on a front surface of the substrate member SM. The mask film MSK7 is patterned so as to expose a region for forming a communication path. The mask film MSK7 is, for example, formed of a silicon oxide film.

Next, as illustrated in FIG. 32, the mask film MSK7 is formed on a front surface of the substrate member SM, and a recessed groove CU1 is formed on the front surface of the substrate member SM by the etching technique in which the mask film MSK7 is used as a mask.

Next, after the patterned mask film MSK7 is removed, a patterned mask film MSK8 is formed on a front surface of the substrate member SM, in which the groove CU1 is formed, by using a photolithography technique and an etching technique, and also a patterned mask film MSK9 is formed on a back surface of the substrate member SM. The mask film MSK8 and the mask film MSK9 are, for example, formed of a silicon oxide film.

Next, as illustrated in FIG. 33, by a both side etching technique in which the patterned mask films MSK8 and MSK9 are used as a mask, the openings OP2 and OP4 are formed on a front surface side of the substrate member SM, and the openings OP1 and OP3 are formed on a back surface side of the substrate member SM. At this time, the openings OP1 and OP2 are formed so as to connect in a thickness direction of the substrate member SM, and the openings OP3 and OP4 are formed so as to connect in a thickness direction of the substrate member SM. Further, the openings OP1 and OP3 are formed so as to separate each other.

Then, the substrate member SM and the sealing substrate 1S are bonded. For example, in the case where a Si substrate is used as the substrate member SM, and a borosilicate glass substrate is used as the sealing substrate 1S, the substrate member SM and the sealing substrate 1S can be bonded by anode bonding.

Next, for example, a gas production material GPM including a solution of a compound including an alkali metal such as cesium azide (CsN3) is dropped on an upper surface of the sealing substrate 1S in the opening OP1. A micropipette and a dispenser can be used to drop the gas production material GPM in a liquid state. Since the openings OP1 and OP3 are separated each other, the gas production material GPM in a liquid state which is dropped on an upper surface of the sealing substrate 1S in the opening OP1 does not flow on an upper surface of the sealing substrate 1S in the opening OP3.

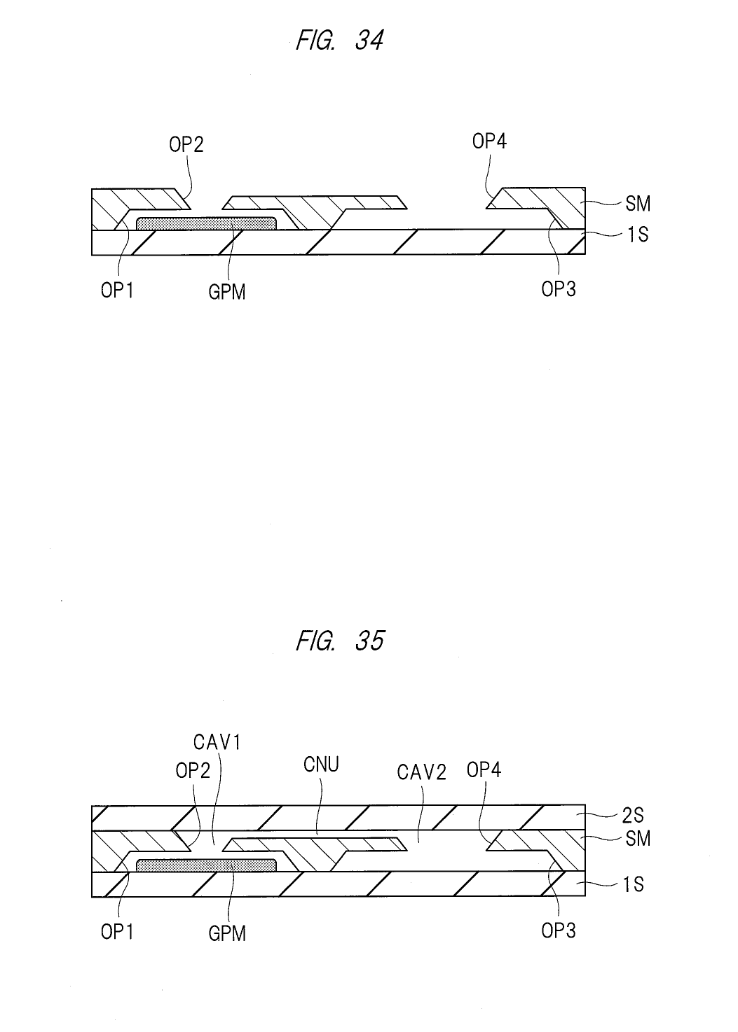

In the fourth embodiment, as illustrated in FIG. 34, a width of the opening OP1 is larger than a width of the opening OP2, and the opening OP2 is included in the opening OP1. A difference in level is formed on a communicating portion between the openings OP1 and OP2. As this result, it is prevented by the difference in level formed in the communicating portion between the openings OP1 and OP2 that the dropped gas production material GPM creeps up on side surfaces of the openings OP1 and OP2. Therefore, according to the fourth embodiment, it is prevented that the dropped gas production material GPM in a liquid state creeps up on side surfaces of the openings OP1 and OP2 and also spills over on a front surface of the substrate member SM.

Next, the gas production material GPM in a liquid state is dried by heating the gas production material GPM in a liquid state. Accordingly, the gas production material GPM in a solid state is precipitated on an upper surface of the sealing substrate 1S in the opening OP1.

Next, as illustrated in FIG. 35, the sealing substrate 2S is bonded on a front surface of the substrate member SM2. Further in this process, for example, in the case where a Si substrate is used as the substrate member SM2, and a borosilicate glass substrate is used as the sealing substrate 2S, the substrate member SM and the sealing substrate 2S can be bonded by anode bonding. Accordingly, the cavity CAV1 including the openings OP1 and OP2 and the cavity CAV2 including the openings OP3 and OP4 are hermetically sealed by the sealing substrates 1S and 2S. Further, in this case, a communication path CNU spacially connecting the cavities CAV1 and CAV2 is formed.

After the cavities CAV1 and CAV2 are sealed, an alkali metal gas and a nitrogen gas are produced from the gas production material GPM by causing a photodecomposition reaction and a thermal decomposition reaction with respect to the gas production material GPM existing on an upper surface of the sealing substrate 1S in the cavity CAV1. Accordingly, an alkali metal gas and a nitrogen gas are filled in the cavity CAV1. Further, the produced alkali metal gas and nitrogen gas are filled also in the cavity CAV2 through the communication path CNU.

As described above, a gas cell in the magnetic field measuring apparatus according to the fourth embodiment can be manufactured. In the fourth embodiment, the cavities CAV1 and CAV2 are formed in a stage before hermetically sealing, but it is not limited thereto. For example, the communication path CNU can be formed by evaporating a part of the substrate member SM by irradiating a region for forming a communication path with a high energy laser light after the cavities CAV1 and CAV2 are hermetically sealed.

The invention by the present inventor has been specifically described above based on the embodiments. However, the present invention is not limited to the embodiments, and can be changed variously without departing from the gist of the invention.

### REFERENCE SIGNS LIST

1S sealing substrate
2S sealing substrate
CAV cavity
CAV1 cavity
CAV2 cavity
CNU communication path
COL coil
CSD1 side surface
CSD2 side surface
CU groove
CU1 groove
GC gas cell
GP gap
GPM gas production material
ISD1 virtual side surface
ISD2 virtual side surface
LD semiconductor laser
LEN1 collimator lens
LEN2 condenser lens
MSK1 mask film
MSK2 mask film
MSK3 mask film
MSK4 mask film
MSK5 mask film
MSK6 mask film
MSK7 mask film
MSK8 mask film
MSK9 mask film
OF1 optical fiber
OF2 optical fiber
OP1 opening
OP2 opening
OP3 opening
OP4 opening
OSD1 side surface
OSD2 side surface
PD photo detector
PR polarizer
SD1 side surface
SD2 side surface
SLR sealing region
SM substrate member
SM1 substrate member
SM2 substrate member
WP wavelength plate

1. A magnetic field measuring apparatus, comprising a gas cell including a first cavity filled with a gas, wherein
the gas cell comprises:
(a) a first sealing substrate;
(b) a second sealing substrate;
(c) a substrate member sandwiched between the first sealing substrate and the second sealing substrate; and
(d) the first cavity penetrating the substrate member,
the first cavity comprises:
(e1) a first opening coming into contact with an upper surface of the first sealing substrate; and
(e2) a second opening coming into contact with a lower surface of the second sealing substrate,
the first cavity is formed by which the first opening and the second opening are communicated, and
a plane size of the first opening is larger than a plane size of the second opening.

2. The magnetic field measuring apparatus according to claim 1, wherein the second opening is included in the first opening in plan view.

3. The magnetic field measuring apparatus according to claim 1, wherein
a first side surface of the first cavity comprises a first opening side surface of the first opening and a second opening side surface of the second opening, and
a second side surface opposing to the first side surface of the first cavity comprises a first opposing side surface opposing to the first opening side surface of the first opening and a second opposing side surface opposing to the second opening side surface of the second opening.

4. The magnetic field measuring apparatus according to claim 3, wherein a virtual side surface provided by extending the second opening side surface on the upper surface side of the first sealing substrate is positioned closer to the first opposing side surface than the first opening side surface.

5. The magnetic field measuring apparatus according to claim 1, wherein the gas is an alkali metal gas.

6. The magnetic field measuring apparatus according to claim 1, wherein a gas production material configured to produce the gas exists on the upper surface of the first sealing substrate in the first cavity.

7. The magnetic field measuring apparatus according to claim 6, wherein the gas production material exists in a solid or liquid state.

8. The magnetic field measuring apparatus according to claim 1, wherein the first sealing substrate and the second sealing substrate are translucent to a light emitted to the gas cell.

9. The magnetic field measuring apparatus according to claim 1, wherein a depth of the first opening is equal to or less than 1 mm.

10. The magnetic field measuring apparatus according to claim 1, wherein
the substrate member comprises:
(f1) a first substrate member; and
(f2) a second substrate member disposed on the first substrate member,
the first opening is formed so as to penetrate the first substrate member, and
the second opening is formed so as to penetrate the second substrate member.

11. The magnetic field measuring apparatus according to claim 1, wherein
a recessed portion is formed on the upper surface of the first sealing substrate,
the second opening is formed so as to penetrate the substrate member, and
the first opening is formed by the recessed portion.

12. The magnetic field measuring apparatus according to claim 11, wherein a depth of the recessed portion is equal to or less than 1 mm.

13. The magnetic field measuring apparatus according to claim 1, wherein
the gas cell is further a second cavity filled with the gas and comprises the second cavity formed so as to penetrate the substrate member and communicate with the first cavity, and
a gas production material for producing the gas is provided on the upper surface of the first sealing substrate in the first cavity, and, on the other hand, the gas production material is not provided on the upper surface of the first sealing substrate in the second cavity.

14. The magnetic field measuring apparatus according to claim 13, wherein the second cavity is irradiated with a light.

15. The magnetic field measuring apparatus according to claim 1, further comprising:
(g) a light source configured to irradiate the gas cell with a light;
(h) a magnetic field production unit configured to apply a static magnetic field and an alternating magnetic field to the gas cell; and
(i) a light detector configured to detect the light which has passed through the gas cell.
